(19) United States
(12) Patent Application Publication
(10) Pub. No.: US 2025/0265379 A1
(43) Pub. Date: Aug. 21, 2025

(54) DISPLAY DEVICE AND COMPUTER-READABLE STORAGE MEDIUM

(71) Applicant: FANUC CORPORATION, Yamanashi (JP)

(72) Inventor: Hiroaki HADA, Yamanashi (JP)

(21) Appl. No.: 18/842,044

(22) PCT Filed: Mar. 24, 2022
(86) PCT No.: PCT/JP2022/014145

§ 371 Date: Apr. 10, 2025

(51) Int. Cl. G06F 30/17

(52) U.S. Cl. CPC G06F 30/17

(57) ABSTRACT

In the present invention, a display device comprises: a tool data acquisition unit that acquires tool data; a material data acquisition unit that acquires material data; a position data acquisition unit that acquires position data indicating the position of a control axis; a simulation unit that executes a machining simulation on the basis of the tool data, the material data, and the position data, and generates a machined surface image showing the machined surface of the material; an association unit that associates the position data and the machined surface image; a waveform image generating unit that generates a waveform image on the basis of the position data; a selection unit that selects a portion of the machined surface image; and a display unit that displays the waveform image corresponding to the portion of the machined surface image when a portion of the machined surface image has been selected.

### TECHNICAL FIELD

The present disclosure relates to a display device and a computer-readable storage medium.

### BACKGROUND ART

Conventionally, in the technical field of machine tools, a technique has been proposed to visually display a movement trajectory of a tool and time-series data indicating a physical quantity related to each control axis of the machine tool.

For example, Patent Literature 1 discloses displaying a movement trajectory of a tool in a three-dimensional space and waveforms of time-series data indicating positions on an X-axis, a Y-axis, an A-axis, a B-axis, and a C-axis. By checking this display, an operator can intuitively grasp the movement on each axis when the tool moves along the movement trajectory.

### CITATION LIST

### Patent Literature

Patent Literature 1: JP 2011-22688 A

### SUMMARY OF INVENTION

### Technical Problem

However, in the technique described in Patent Literature 1, a machined surface of a workpiece is not drawn. Thus, when the tool moves along the movement trajectory, it is difficult for the operator to grasp which part of the workpiece is being machined. Therefore, there is a possibility that the operator cannot grasp the correspondence relationship between the position on the machined surface of the workpiece being machined by the tool and the physical quantity on each control axis acquired when the machined surface is being machined.

Therefore, there is a demand for a display device that enables the operator to easily grasp a correspondence relationship between a position on a machined surface of a workpiece and a physical quantity on each control axis acquired when the machined surface is being machined.

### Solution to Problem

A display device includes: a tool data acquisition unit that acquires tool data indicating a shape of a tool; a material data acquisition unit that acquires material data indicating a shape of a material; a position data acquisition unit that acquires position data indicating a position on each of a plurality of control axes; a simulation unit that executes a machining simulation, based on the tool data, the material data, and the position data to generate a machined surface image indicating a machined surface of the material; an association unit that associates the position data with the machined surface image; a waveform image generation unit that generates a waveform image indicating a change in the position data or in a physical quantity on each of the plurality of control axes, based on the position data or based on the physical quantity, the physical quantity being acquired at timing when the position data is acquired; a selection unit that selects a part of the machined surface image or a part of the waveform image; and a display unit that displays, when a part of the machined surface image is selected, the waveform image corresponding to the part of the machined surface image, and displays, when a part of the waveform image is selected, a part of the machined surface image corresponding to the part of the waveform image on a display screen.

A computer-readable storage medium stores a command that causes a computer to execute acquiring tool data that indicates a shape of a tool, acquiring material data that indicates a shape of a material, acquiring position data that indicates a position on each of a plurality of control axes, executing a machining simulation, based on the tool data, the material data, and the position data to generate a machined surface image indicating a machined surface of the material, associating the position data with the machined surface image, generating a waveform image indicating a change in the position data or in a physical quantity on each of the plurality of control axes, based on the position data or based on the physical quantity, the physical quantity being acquired at timing when the position data is acquired, selecting a part of the machined surface image or a part of the waveform image, and displaying, when a part of the machined surface image is selected, the waveform image corresponding to the part of the machined surface image, and displaying, when a part of the waveform image is selected, a part of the machined surface image corresponding to the part of the waveform image on a display screen.

### Advantageous Effects of Invention

According to one aspect of the present disclosure, an operator can easily grasp a correspondence relationship between a position of a workpiece on a machined surface of a workpiece and a physical quantity on each control axis acquired when the machined surface is being machined.

### BRIEF DESCRIPTION OF DRAWINGS

FIG. 1 is a block diagram illustrating an example of a hardware configuration of a machining device.

FIG. 2 is a block diagram illustrating an example of functions of a numerical controller.

FIG. 3A is a diagram for explaining an association between position data and a machined surface image.

FIG. 3B is a diagram for explaining the association between the position data and the machined surface image.

FIG. 3C is a diagram for explaining the association between the position data and the machined surface image.

FIG. 4A is a diagram illustrating an example of a machined surface image.

FIG. 4B is a diagram illustrating an example of the machined surface image.

FIG. 5 is a diagram illustrating an example of a waveform image.

FIG. 6 is a flowchart illustrating an example of a flow of processing executed by a display device.

FIG. 7 is a diagram illustrating an example of a waveform image.

FIG. 8 is a flowchart illustrating an example of a flow of processing executed by the display device.

FIG. 9 is a block diagram illustrating an example of functions of a display device mounted on a numerical controller.

FIG. 10 is a diagram illustrating an example of a waveform image generated based on physical quantity data.

FIG. 11 is a block diagram illustrating an example of functions of a display device.

FIG. 12 is a diagram illustrating an example of functions of a display device.

FIG. 13 is a diagram illustrating an example of a machined surface image on which a difference image is drawn.

### DESCRIPTION OF EMBODIMENT

Hereinafter, a display device according to an embodiment of the present disclosure will be described with reference to the drawings. Note that not all combinations of features described in the following embodiments are necessarily required for solving the problem. Further, an unnecessarily detailed description may be omitted. The following description of the embodiment and the drawings are provided for those skilled in the art to fully understand the present disclosure, and are not intended to limit the scope of the claims.

The display device is a device that displays, on a display screen, a correspondence relationship between a machined surface image indicating a machined surface of a material to be machined and a physical quantity acquired when the machined surface is machined.

The display device is mounted on, for example, a numerical controller that controls the machining device. The display device may be mounted on a server connected to the numerical controller or a personal computer (PC). Hereinafter, the display device mounted on the numerical controller will be described.

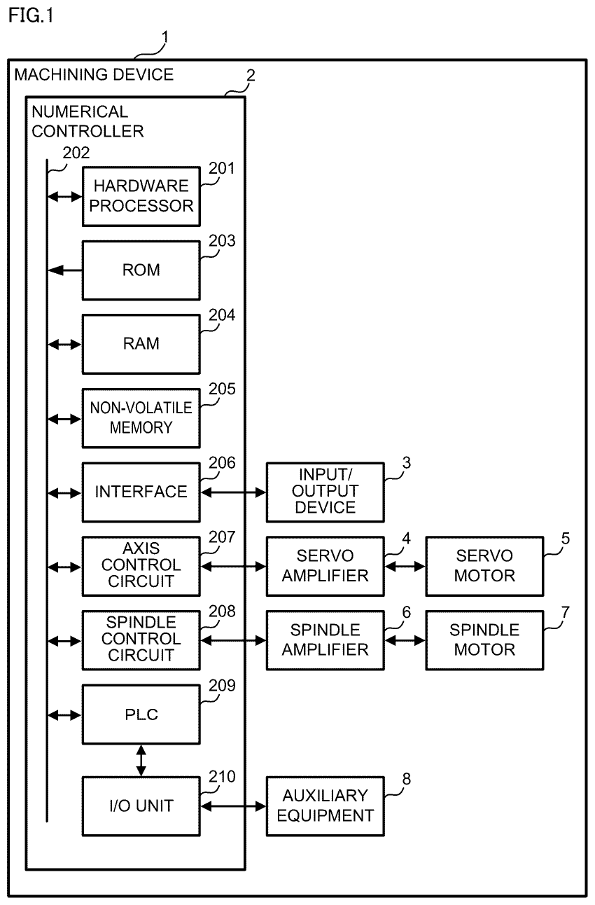

FIG. 1 is a block diagram illustrating an example of a hardware configuration of a machining device that includes a numerical controller. A machining device 1 includes a machine tool, a wire electric discharge machine, an injection molding machine, and a three-dimensional printer. The machine tool includes a lathe, a machining center, and a combined machining device.

The machining device 1 includes a numerical controller 2, an input/output device 3, a servo amplifier 4, a servo motor 5, a spindle amplifier 6, a spindle motor 7, and auxiliary equipment 8.

The numerical controller 2 is a device that controls the entire machining device 1. The numerical controller 2 includes a hardware processor 201, a bus 202, a read-only memory (ROM) 203, a random-access memory (RAM) 204, and a non-volatile memory 205.

The hardware processor 201 is a processor that controls the entire numerical controller 2 according to a system program. The hardware processor 201 reads a system program and the like stored in the ROM 203 via the bus 202, and performs various processes based on the system program. The hardware processor 201 controls the servo motor 5 and the spindle motor 7 based on a machining program. The hardware processor 201 is, for example, a central processing unit (CPU) or an electronic circuit.

The hardware processor 201, for each control cycle, for example, analyzes the machining program and outputs control commands to the servo motor 5 and the spindle motor 7.

The bus 202 is a communication path that connects each piece of hardware in the numerical controller 2 to each other. Each piece of hardware in the numerical controller 2 exchanges data via the bus 202.

The ROM 203 is a storage device that stores a system program and the like for controlling the entire numerical controller 2. The ROM 203 is a computer-readable storage medium.

The RAM 204 is a storage device that temporarily stores various data. The RAM 204 functions as a work area for the hardware processor 201 to process various data.

The non-volatile memory 205 is a storage device that holds data even in a state where the power of the machining device 1 is turned off and no power is supplied to the numerical controller 2. The non-volatile memory 205 stores, for example, a machining program and various parameters. The non-volatile memory 205 is a computer-readable storage medium. The non-volatile memory 205 includes, for example, a memory backed up by a battery or a solid-state drive (SSD).

The numerical controller 2 further includes an interface 206, an axis control circuit 207, a spindle control circuit 208, a programmable logic controller (PLC) 209, and an input/output (I/O) unit 210.

The interface 206 connects the bus 202 and the input/output device 3. The interface 206 sends, for example, various data processed by the hardware processor 201 to the input/output device 3.

The input/output device 3 receives various data via the interface 206 and displays the various data. The input/output device 3 receives inputs of various data and transmits the various data to, for example, the hardware processor 201 via the interface 206.

The input/output device 3 is, for example, a touch panel. When the input/output device 3 is a touch panel, the input/output device 3 is, for example, a capacitive touch panel. Note that the touch panel is not limited to a capacitive touch panel, and may be a touch panel of another type. The input/output device 3 is installed on an operation panel (not illustrated) in which the numerical controller 2 is stored.

The axis control circuit 207 is a circuit that controls the servo motor 5. The axis control circuit 207 receives a control command from the hardware processor 201 and transmits various commands for driving the servo motor 5 to the servo amplifier 4. The axis control circuit 207 sends, for example, a torque command for controlling the torque of the servo motor 5 to the servo amplifier 4.

The servo amplifier 4 receives a command from the axis control circuit 207 and supplies a current to the servo motor 5.

The servo motor 5 is driven by a current supplied from the servo amplifier 4. The servo motor 5 is provided on each control axis of the machining device 1. When the machining device 1 is a five-axis machining device, the servo motor 5 includes, for example, an X-axis servo motor, a Y-axis servo motor, a Z-axis servo motor, an A-axis servo motor, and a C-axis servo motor.

The servo motor 5 is connected to, for example, a ball screw that drives a tool holder. When the servo motor 5 is driven, a component of the machining device 1, such as a tool holder, moves in a direction along a predetermined control axis. The servo motor 5 incorporates an encoder (not illustrated) that detects a position and a feed speed on the control axis. Position feedback information and speed feedback information, which indicate the position on the control axis and the feed speed on the control axis detected by the encoder, respectively, are fed back to the axis control circuit 207. As a result, the axis control circuit 207 performs feedback control of the control axis.

The spindle control circuit 208 is a circuit for controlling the spindle motor 7. The spindle control circuit 208 receives a control command from the hardware processor 201 and transmits a command for driving the spindle motor 7 to the spindle amplifier 6. The spindle control circuit 208 transmits, for example, a spindle speed command for controlling the rotation speed of the spindle motor 7 to the spindle amplifier 6.

The spindle amplifier 6 receives a command from the spindle control circuit 208 and supplies a current to the spindle motor 7.

The spindle motor 7 is driven by a current supplied from the spindle amplifier 6. The spindle motor 7 is connected to the spindle and rotates the main spindle.

The PLC 209 is a device that executes a ladder program to control the auxiliary equipment 8. The PLC 209 transmits a command to the auxiliary equipment 8 via the I/O unit 210.

The I/O unit 210 is an interface that connects the PLC 209 and the auxiliary equipment 8. The I/O unit 210 transmits the command received from the PLC 209 to the auxiliary equipment 8.

The auxiliary equipment 8 is equipment that is installed in the machining device 1 and performs an auxiliary operation in the machining device 1. The auxiliary equipment 8 operates based on a command received from the I/O unit 210. The auxiliary equipment 8 may be equipment installed around the machining device 1. The auxiliary equipment 8 is, for example, a tool changer, a cutting liquid injector, or an opening/closing door drive.

Next, the functions of the numerical controller 2 will be described.

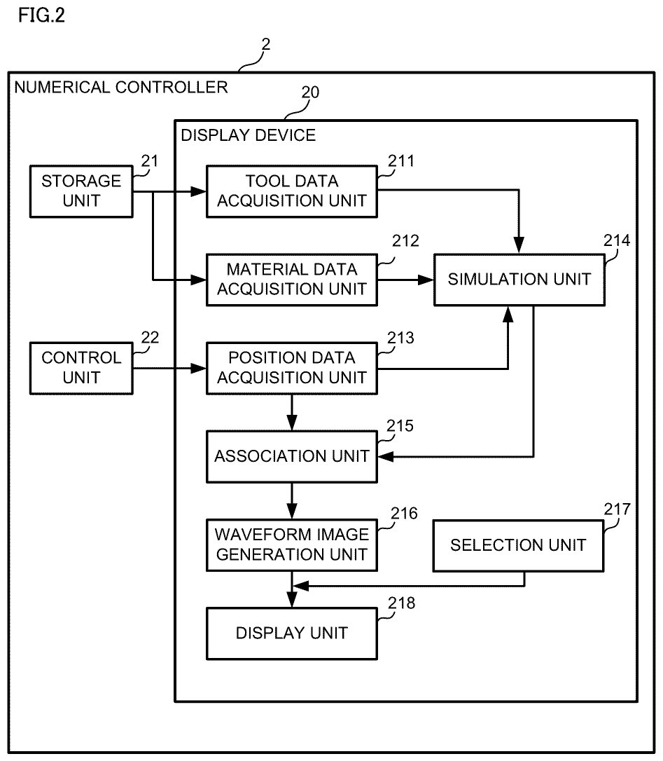

FIG. 2 is a block diagram illustrating an example of the functions of the numerical controller 2. The numerical controller 2 includes a display device 20. In addition, the numerical controller 2 includes a storage unit 21 and a control unit 22.

The storage unit 21 is implemented by storing various data and various programs in the RAM 204 or the non-volatile memory 205. The control unit 22 is implemented by the hardware processor 201 performing arithmetic processing using the system program stored in the ROM 203, the machining program and various data stored in the non-volatile memory 205.

The storage unit 21 stores tool data indicating a shape of a tool and material data indicating a shape of a material. The storage unit 21 also stores the machining program.

The tool data is data indicating the shape of the tool. The tool is, for example, a cutting tool. The tool data includes, for example, data indicating a tool type. The tool type includes a square end mill, a ball end mill, a milling cutter, and a bite. The tool data may include data indicating a blade diameter, a blade length, a shank diameter, and a total length. The tool data may be three-dimensional computer-aided design (CAD) data indicating the shape of the tool.

The material data is data indicating the shape of the material before machining. The material is a workpiece to be machined by the machining device 1. The shape of the material includes a rectangular parallelepiped shape, a cylindrical shape, and a cylindrical shape. The material data includes data indicating the size of the material. The data indicating the size includes data indicating the length, height, thickness, and depth of each side. The material data may be three-dimensional CAD data indicating the shape of the material.

The control unit 22 controls one or more control axes. The control unit 22 controls each control axis based on the machining program stored in the storage unit 21. The one or more control axes include at least one of an X-axis, a Y-axis, or a Z-axis. The plurality of control axes may further include at least one of an A-axis, a B-axis, or a C-axis.

The display device 20 includes a tool data acquisition unit 211, a material data acquisition unit 212, a position data acquisition unit 213, a simulation unit 214, an association unit 215, a waveform image generation unit 216, a selection unit 217, and a display unit 218. The tool data acquisition unit 211, the material data acquisition unit 212, the position data acquisition unit 213, the simulation unit 214, the association unit 215, the waveform image generation unit 216, the selection unit 217, and the display unit 218 are implemented, for example, by the hardware processor 201 performing arithmetic processing using a display program stored in the ROM 203 and various data stored in the non-volatile memory 205.

The tool data acquisition unit 211 acquires the tool data stored in the storage unit 21 of the numerical controller 2. The tool data acquisition unit 211 may acquire the tool data from an external device connected to the numerical controller 2. Examples of the external device include a server and a PC connected to the numerical controller 2 via a network.

The material data acquisition unit 212 acquires the material data stored in the storage unit 21 of the numerical controller 2. The material data acquisition unit 212 may acquire the material data from the external device connected to the numerical controller 2.

The position data acquisition unit 213 acquires position data indicating the positions on the plurality of control axes of the machining device 1. The position data is, for example, feedback data from a detector that detects positions on the plurality of control axes of the machining device 1. In this case, the position data acquisition unit 213 acquires position data every predetermined sampling time from the detector that detects the position on the control axis. That is, the position data acquired by the position data acquisition unit 213 is time-series data. The position data acquisition unit 213 acquires the position data via the control unit 22.

The detector that detects the positions on the plurality of control axes is, for example, the servo motor 5. The detector may be a linear encoder installed along each linear axis of the machining device 1 or a rotary encoder installed around each rotation axis.

The position data may be data indicating coordinate values in a predetermined coordinate system converted from the feedback data. The position data may be, for example, data indicating the position of the tool tip. In this case, the position data is, for example, data indicating positions on the X-axis, the Y-axis, and the Z-axis of the tool in an orthogonal coordinate system. The orthogonal coordinate system may be a machine coordinate system or a workpiece coordinate system. The position data is not limited to the feedback data, and may be command data for commanding the rotational position of the servo motor 5.

The simulation unit 214 executes a machining simulation based on the tool data acquired by the tool data acquisition unit 211, the material data acquired by the material data acquisition unit 212, and the position data acquired by the position data acquisition unit 213 to generate a machined surface image indicating the machined surface of the material.

The machined surface image is an image of a surface newly generated by the tool cutting an unnecessary portion from the material based on the machining program. The machined surface image will be described in detail later.

The association unit 215 associates the position data of the tool acquired by the position data acquisition unit 213 with the machined surface image generated by the simulation unit 214.

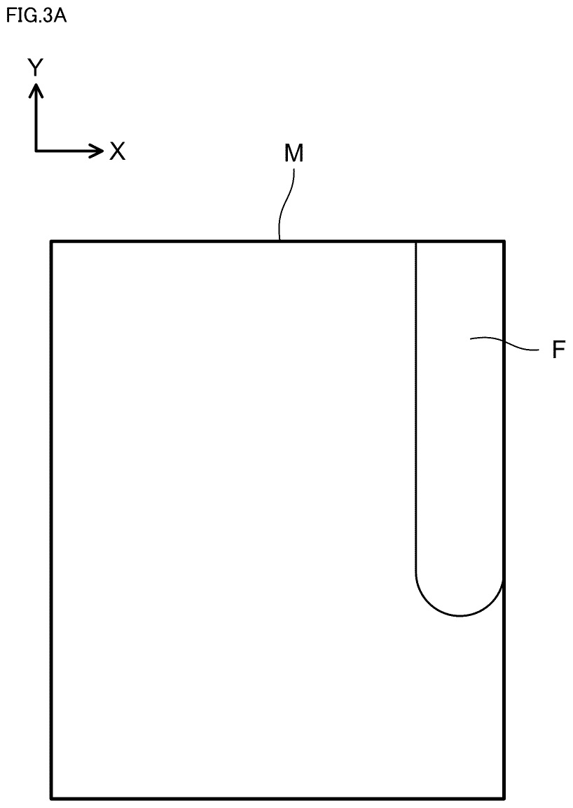

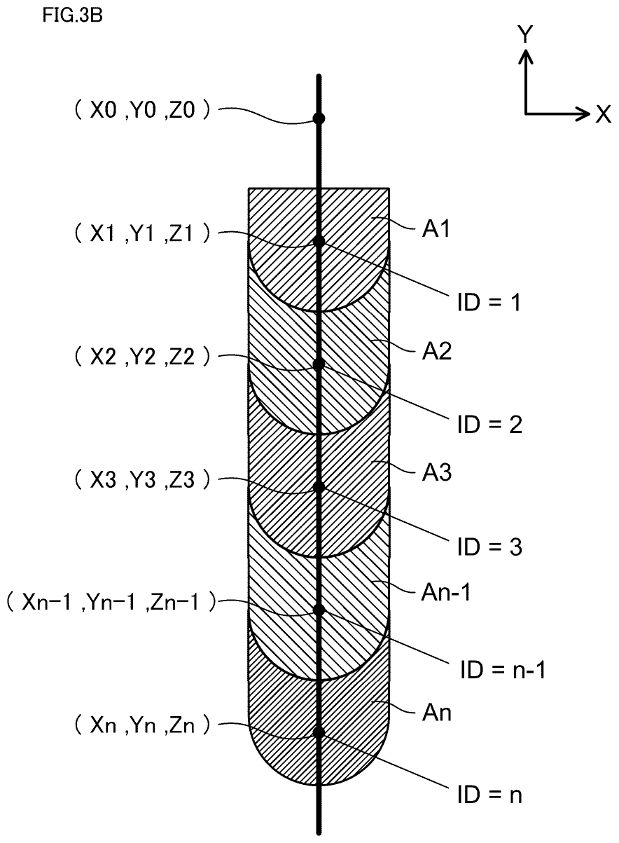

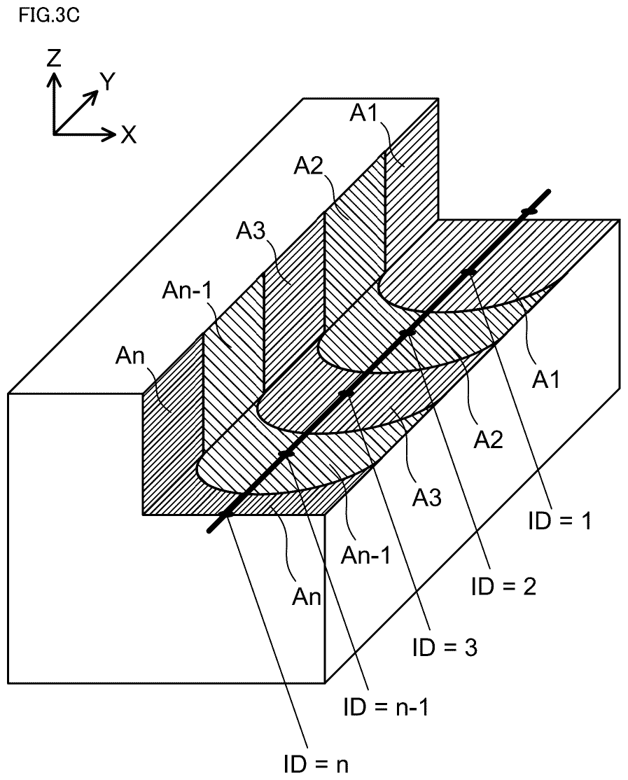

FIGS. 3A to 3C are diagrams for explaining the association between the position data and the machined surface image. FIG. 3A is a diagram illustrating an image of a rectangular parallelepiped material M when the material M is viewed in the minus direction from the plus direction of the Z-axis. This image shows that a part of the upper surface has been cut by the square end mill. The cut portion is a machined surface F.

FIG. 3B is an enlarged view of the machined surface F illustrated in FIG. 3A. (X1, Y1, Z1), (X2, Y2, Z2), (X3, Y3, Z3), (Xn-1, Yn-1, Zn-1), and (Xn, Yn, Zn) illustrated in FIG. 3B are position data acquired at every predetermined sampling time while the tool is machining the material M. An identification information ID may be attached to each position data.

The association unit 215 associates the machined surface image of the machined surface F machined by the tool during a predetermined sampling time t with the position data.

For example, the association unit 215 associates a machined surface image A1 of the machined surface F machined by the movement of the position of the tool from (X0, Y0, Z0) to (X1, Y1, Z1) during the sampling time t with position data (X1, Y1, Z1). The association unit 215 associates a machined surface image A2 of the machined surface F machined by the movement of the position of the tool from (X1, Y1, Z1) to (X2, Y2, Z2) during the next sampling time t with position data (X2, Y2, Z2). Further, the association unit 215 associates a machined surface image A3 of the machined surface F machined by the movement of the position of the tool from (X2, Y2, Z2) to (X3, Y3, Z3) during the next sampling time t with position data (X3, Y3, Z3).

Similarly, the association unit 215 associates the machined surface image An-1 of the machined surface F machined by the movement of the position of the tool from (Xn-2, Yn-2, Zn-2) to (Xn-1, Yn-1, Zn-1) during the sampling time t with position data (Xn-1, Yn-1, Zn-1). Further, the association unit 215 associates the machined surface image An of the machined surface F machined by the movement of the position of the tool from (Xn-1, Yn-1, Zn-1) to (Xn, Yn, Zn) during the next sampling time t with position data (Xn, Yn, Zn).

FIG. 3C illustrates a machined surface image when a part of the material M of FIG. 3A is viewed from diagonally front. By cutting the upper surface of the material M with the square end mill, a machined surface F parallel to the x-y plane and a machined surface F parallel to the y-z plane are formed on the material M. That is, the machined surface image A1, the machined surface image A2, the machined surface image A3, the machined surface image An-1, and the machined surface image An each include a machined surface image of the machined surface F parallel to the x-y plane and a machined surface image of the machined surface F parallel to the y-z plane. Here, the description returns to FIG. 2.

The waveform image generation unit 216 generates a waveform image based on the position data. The waveform image is an image of time-series data indicating the position on each of the plurality of control axes. The waveform image will be described in detail later.

The display unit 218 displays, on a display screen, the machined surface image associated with the position data by the association unit 215. The display unit 218 may display the waveform image on the display screen together with the machined surface image.

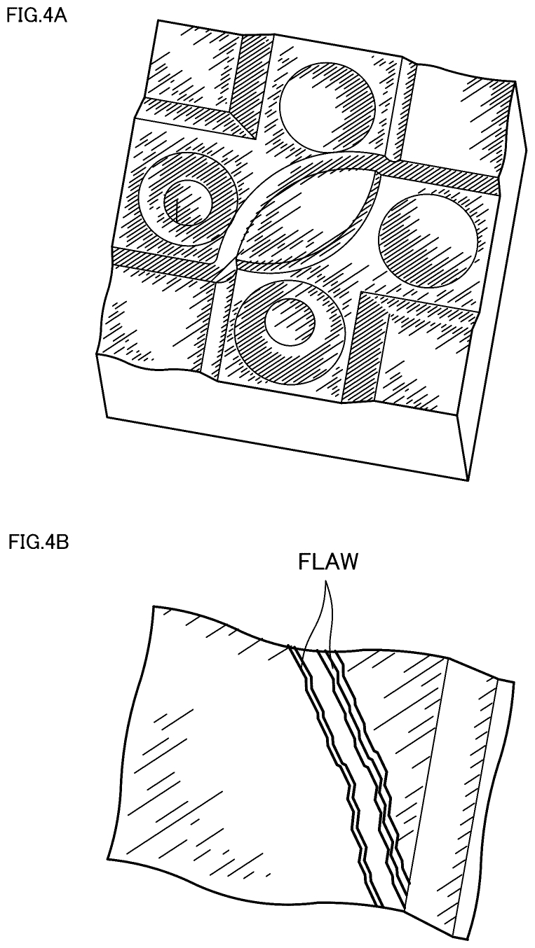

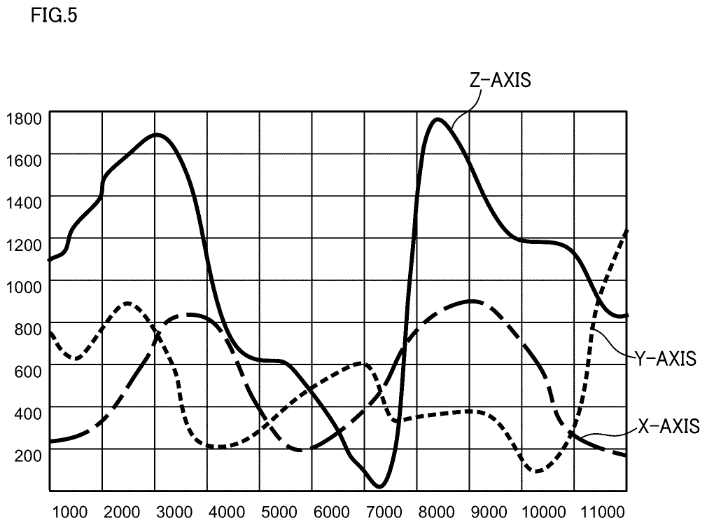

FIGS. 4A and 4B are diagrams illustrating an example of the machined surface image. FIG. 4B is an enlarged view of a part of the machined surface image illustrated in FIG. 4A. An operator views the machined surface image displayed on the display screen to check whether or not a quality-related defect, such as a flaw, has occurred on the surface of the machined surface image generated by the simulation.

When the operator finds that a flaw has occurred on the machined surface F by viewing the machined surface image, the display unit 218 enlarges and displays a portion where the flaw has been formed, as illustrated in FIG. 4B, based on the operator's operation. Here, the operator's operation is an operation for enlarging the machined surface image. When the input/output device 3 is a touch panel, the operator enlarges the machined surface image by performing a pinch-out operation on the touch panel, for example.

The selection unit 217 selects a part of the machined surface image. The selection unit 217 selects a part of the machined surface image based on, for example, the operator's selection operation for a part of the machined surface image displayed on the display screen of the input/output device 3. The operator performs a selection operation by touching a flaw portion of the enlarged and displayed machined surface image, for example.

When a part of the machined surface image is selected, the display unit 218 displays a waveform image corresponding to the part of the machined surface image. The waveform image corresponding to a part of the machined surface image is an image of a waveform generated based on the position data associated with the machined surface image by the association unit 215.

FIG. 5 is a diagram illustrating an example of the waveform image. The waveform image indicates changes in position data on the X-axis, position data on the Y-axis, and position data on the Z-axis. That is, the waveform image is an image indicating the temporal transition of the position data indicating the position on one or more control axes.

The waveform image indicates the position on each control axis when the vicinity of the machined surface F corresponding to a part of the machined surface image selected by the selection unit 217 is being machined. For example, the waveform image in FIG. 5 is an image indicating the position on each control axis when the periphery of the flaw portion drawn in the machined surface image in FIG. 4B is being machined.

In the waveform image of FIG. 5, the waveform indicating the position on the Z-axis greatly fluctuates. Therefore, the operator can estimate that the flaw drawn on the machined surface image is due to the influence of the change in the position on the Z-axis.

Next, processing executed by the display device 20 will be described.

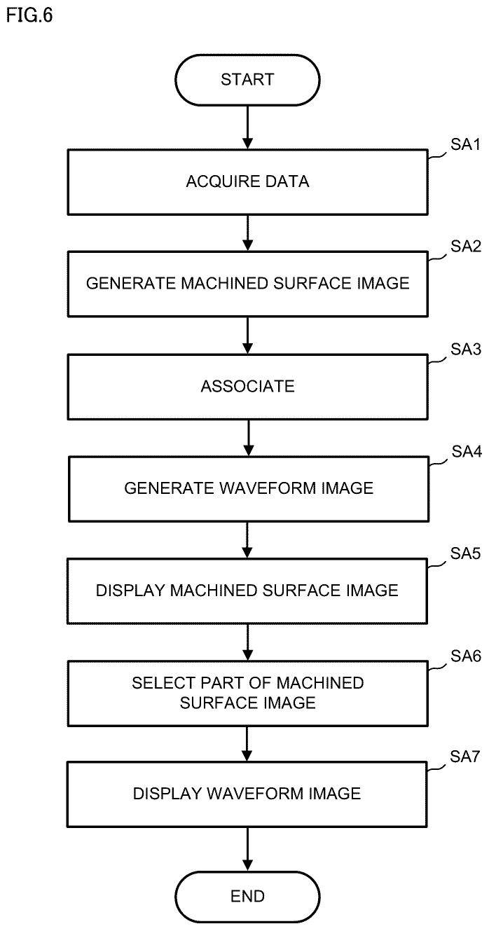

FIG. 6 is a flowchart illustrating an example of the processing executed by display device 20. When the machining program is executed and the operation of the machining device 1 is started, the display device 20 acquires data (step SA1). Here, the tool data acquisition unit 211 acquires tool data. The material data acquisition unit 212 acquires material data. The position data acquisition unit 213 starts acquiring position data.

Note that the material M does not necessarily need to be actually machined during the operation of the machining device 1. That is, the machining device 1 may be operated without the installation of the material M in the machining device 1.

Next, the simulation unit 214 executes a machining simulation based on the tool data, the material data, and the position data to generate a machined surface image indicating the machined surface F of the material M (step SA2). Note that the simulation unit 214 may execute the simulation during the operation of the machining device 1. In addition, the simulation unit 214 may not necessarily execute the simulation during the operation of the machining device 1. For example, the position data acquisition unit 213 may store position data acquired during the execution of the machining program in a predetermined storage unit (not illustrated), and the simulation unit 214 may execute the simulation using the position data stored in the storage unit.

Next, the association unit 215 associates the position data with the machined surface image (step SA3).

Subsequently, the waveform image generation unit 216 generates a waveform image based on the position data (step SA4). For example, the waveform image generation unit 216 generates a waveform image after the operation of the machining device 1 ends.

Next, the display unit 218 displays the machined surface image on the display screen (step SA5). At this time, the display unit 218 may display the waveform image on the display screen together with the machined surface image.

Next, the selection unit 217 selects a part of the machined surface image, based on, for example, the operator's operation (step SA6).

Subsequently, the display unit 218 displays the waveform image corresponding to the part of the machined surface image (step SA7), and ends the processing.

As described above, the display device 20 includes: a tool data acquisition unit 211 that acquires tool data indicating a shape of a tool; a material data acquisition unit 212 that acquires material data indicating a shape of a material M a position data acquisition unit 213 that acquires position data indicating a position on each of a plurality of control axes; a simulation unit 214 that executes a machining simulation, based on the tool data, the material data, and the position data to generate a machined surface image indicating a machined surface F of the material M; an association unit 215 that associates the position data with the machined surface image; a waveform image generation unit 216 that generates a waveform image indicating a change in the position data or in a physical quantity on each of the plurality of control axes, based on the position data or based on the physical quantity, the physical quantity being acquired at timing when the position data is acquired, a selection unit 217 that selects a part of the machined surface image; and a display unit 218 that displays, when a part of the machined surface image is selected, a waveform image corresponding to the part of the machined surface image on a display screen.

Therefore, the display device 20 enables the operator to easily grasp the correspondence relationship between the position of the workpiece on the machined surface F and the position on each control axis acquired when the machined surface F is being machined. Specifically, by the operator selecting a part of the machined surface image in which a flaw or the like is drawn, the display device 20 can display, on the display screen, a part of the waveform image corresponding to the part of the machined surface image in which the flaw is drawn. This enables the operator to estimate on which one of the plurality of control axes a defect has occurred.

The display device 20 may display, based on the operator's selection operation for a part of the waveform image, a machined surface image corresponding to the part of the waveform image. In this case, the display unit 218 displays the waveform image on the display screen, and receives a selection operation performed by the operator on a part of the waveform image.

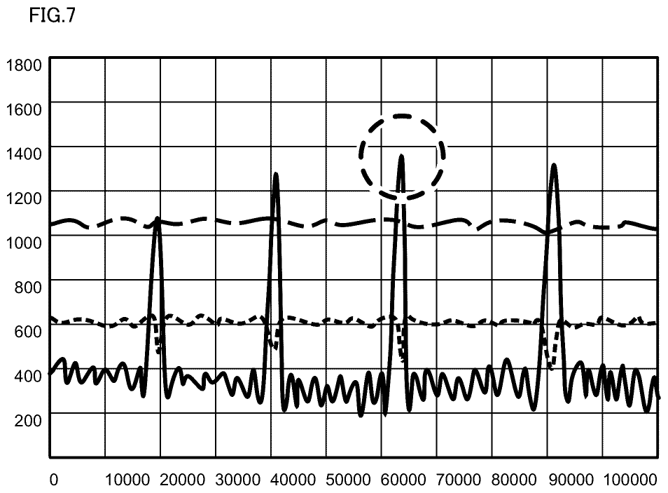

FIG. 7 is a diagram illustrating an example of the waveform image. When the operator views the waveform image and estimates that an abnormality has appeared on the control axis in the waveform, the display unit 218 enlarges and displays a part of the waveform image based on the operator's operation. Here, the operator's operation is an operation for enlarging the waveform image. When the input/output device 3 is a touch panel, the operator enlarges the waveform image by performing a pinch-out operation on the touch panel, for example.

Next, the selection unit 217 selects a part of the waveform image. The selection unit 217 selects a part of the waveform image based on, for example, the operator's selection operation for a part of the waveform image displayed on the display screen of the input/output device 3. The operator performs a selection operation by touching a part of the enlarged and displayed waveform image, for example. Note that the selection unit 217 may automatically select, for example, a portion where the amplitude of the waveform exceeds a predetermined threshold regardless of the operator's selection operation.

When a part of the waveform image is selected, the display unit 218 displays a part of the machined surface image corresponding to the part of the waveform image. The machined surface image corresponding to the part of the waveform image is a machined surface image associated with position data that is an element constituting the waveform image.

For example, when a part of the waveform image surrounded by the broken line in FIG. 7 is selected, the display unit 218 displays, for example, the machined surface image illustrated in FIG. 4B on the display screen. As a result, the display unit 218 can display, on the display screen, the machined surface image corresponding to the part of the waveform image.

Next, a description will be given of a flow of processing executed by the display device 20 when the display device 20 displays, based on the operator's selection operation for a part of the waveform image, a machined surface image corresponding to the part of the waveform image.

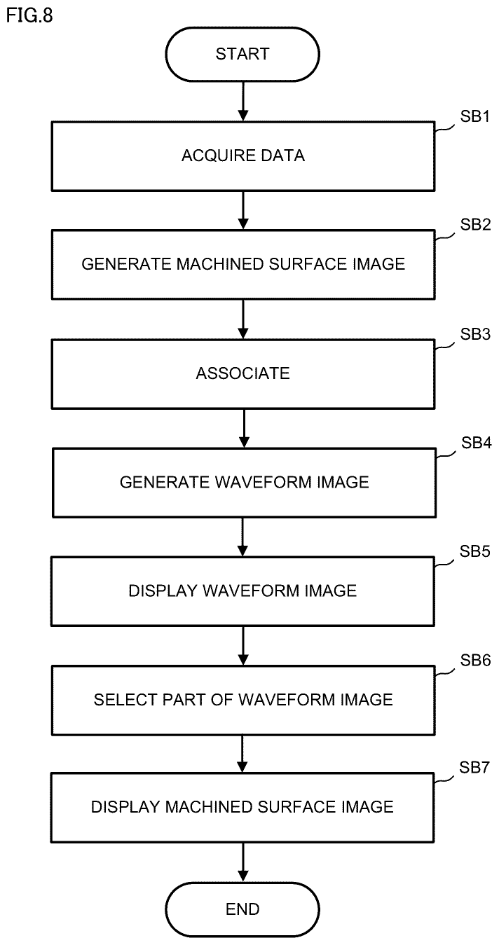

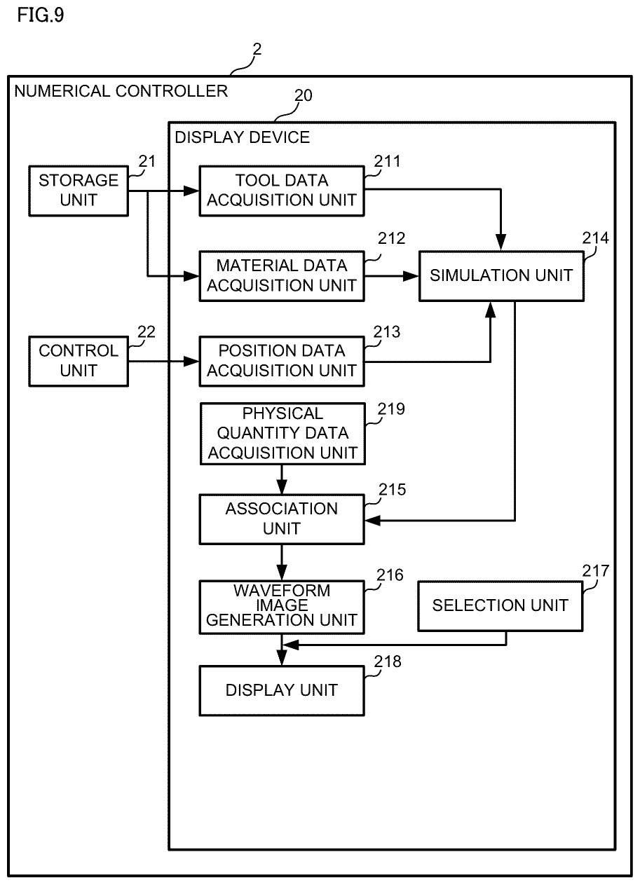

FIG. 8 is a flowchart illustrating an example of a flow of processing executed by the display device 20. The processes from step SB1 to step SB4 are the same as the processes from step SA1 to step SA4 illustrated in FIG. 6, and hence description thereof is omitted here.

When the process of step SB4 ends, the display unit 218 displays the waveform image on the display screen (step SB5).

Next, the selection unit 217 selects a part of the waveform image, for example, based on the operator's operation (step SB6).

Next, the display unit 218 displays the machined surface image corresponding to the part of the waveform image (step SB7), and ends the processing.

As described above, the display device 20 includes: a tool data acquisition unit 211 that acquires tool data indicating a shape of a tool; a material data acquisition unit 212 that acquires material data indicating a shape of a material M; a position data acquisition unit 213 that acquires position data indicating a position on each of a plurality of control axes; a simulation unit 214 that executes a machining simulation, based on the tool data, the material data, and the position data to generate a machined surface image indicating a machined surface F of the material M; an association unit 215 that associates the position data with the machined surface image; a waveform image generation unit 216 that generates a waveform image indicating a change in the position data or in a physical quantity on each of the plurality of control axes, based on the position data or based on the physical quantity, the physical quantity being acquired at timing when the position data is acquired, a selection unit 217 that selects a part of the machined surface image or a part of the waveform image; and a display unit 218 that displays, when a part of the machined surface image is selected, a waveform image corresponding to the part of the machined surface image on a display screen.

Therefore, the display device 20 enables the operator to easily grasp the correspondence relationship between the position of the workpiece on the machined surface F and the position on each control axis acquired when the machined surface F is being machined. Specifically, when the operator selects a part of the waveform image in which an abnormality is estimated to have appeared on the control axis in the waveform, the display device 20 can display a part of the machined surface image corresponding to the part of the waveform image. This enables the operator to quickly find a portion of the machined surface F where a flaw or the like may occur.

In the embodiment described above, the display device 20 displays, on the display screen, the correspondence relationship between the machined surface image indicating the machined surface F of the material M to be machined and the position on each control axis when the machined surface F is machined. However, the display device 20 displays, on the display screen, the correspondence relationship between the machined surface image indicating the machined surface F of the material M to be machined and the physical quantity on each control axis when the machined surface F is machined.

FIG. 9 is a block diagram illustrating an example of functions of a display device 20 mounted on the numerical controller 2. The display device 20 illustrated in FIG. 9 differs from the display device 20 illustrated in FIG. 2 in including a physical quantity data acquisition unit 219. Therefore, here, the physical quantity data acquisition unit 219 and the function related thereto will be described, and the description of the same functions as the functions described with reference to FIG. 2 will be omitted.

The physical quantity data acquisition unit 219 is implemented, for example, by the hardware processor 201 performing arithmetic processing using the display program stored in the ROM 203 and various data stored in the non-volatile memory 205.

The physical quantity data acquisition unit 219 acquires physical quantity data indicating physical quantities on a plurality of control axes. The physical quantity is a physical quantity other than the position, and includes at least one of speed, acceleration, jerk, or torque.

The physical quantity data acquisition unit 219 acquires a physical quantity based on a signal from a detector that detects the physical quantity from each control axis, for example. The physical quantity data acquisition unit 219 acquires physical quantity data from the detector every predetermined sampling time. That is, the physical quantity data acquired by the physical quantity data acquisition unit 219 is time-series data.

The detector that detects the physical quantity on the control axis is, for example, the servo motor 5. For example, the physical quantity data acquisition unit 219 acquires physical quantity data indicating the speed of each control axis by detecting the amount of change per unit time in the rotational position of the servo motor. In addition, the physical quantity data acquisition unit 219 acquires physical quantity data indicating the magnitude of the torque of the servo motor based on the current value of the current supplied to the servo motor.

The waveform image generation unit 216 generates a waveform image based on the physical quantity data indicating the physical quantities on the plurality of control axes acquired at the timing when the position data is acquired. For example, the same index is assigned to the position data and the physical quantity data according to the time of acquisition. Thereby, the waveform image generation unit 216 generates the waveform image of the physical quantity data acquired at the timing when the position data is acquired. Here, the physical quantity data acquired at the timing when the position data is acquired is not necessarily data acquired at exactly the same time. For example, the position data and the physical quantity data may be data acquired while being shifted from each other by several milliseconds to several tens of milliseconds.

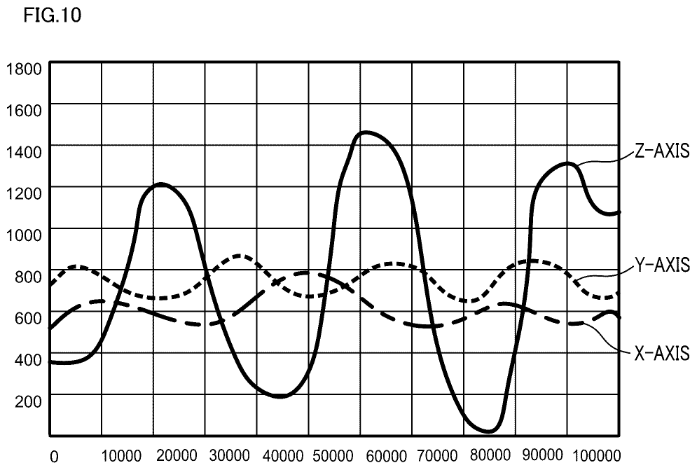

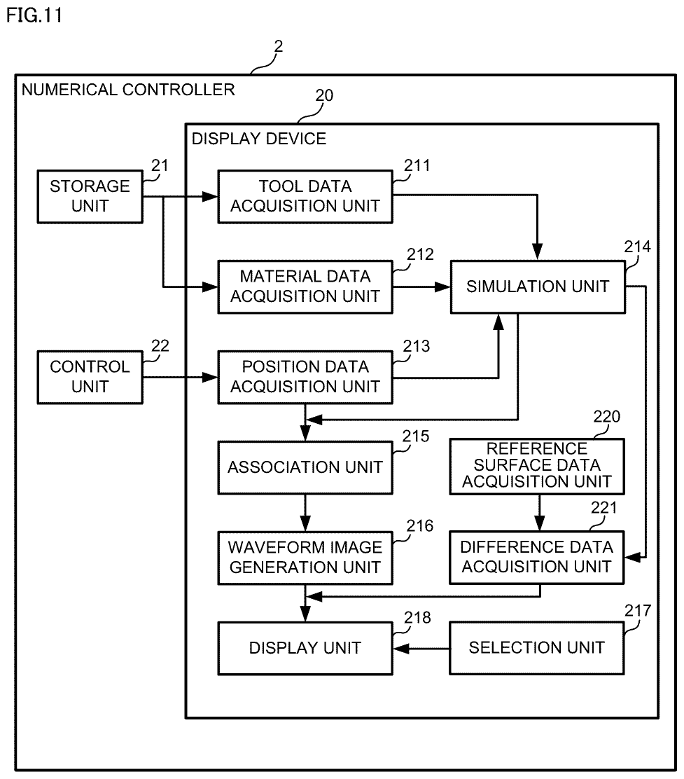

FIG. 10 is a diagram illustrating an example of a waveform image generated based on physical quantity data. The waveform image illustrated in FIG. 10 is, for example, a waveform image of a waveform indicating a change in torque of each control axis.

When the waveform image generation unit 216 generates the waveform image, the selection unit 217 selects a part of the machined surface image or a part of the waveform image.

For example, when the display unit 218 displays the machined surface image and the waveform image on the display screen, and the operator performs a selection operation for a part of the machined surface image, the selection unit 217 selects a part of the machined surface image. On the other hand, when the operator performs a selection operation for a part of the waveform image, the selection unit 217 selects a part of the waveform image.

When a part of the machined surface image is selected, the display unit 218 displays a waveform image corresponding to the part of the machined surface image. On the other hand, when a part of the waveform image is selected, the display unit 218 displays a part of the machined surface image corresponding to the part of the waveform image.

As described above, the display device 20 includes: a tool data acquisition unit 211 that acquires tool data indicating a shape of a tool; a material data acquisition unit 212 that acquires material data indicating a shape of a material M; a position data acquisition unit 213 that acquires position data indicating a position on each of a plurality of control axes; a simulation unit 214 that executes a machining simulation, based on the tool data, the material data, and the position data to generate a machined surface image indicating a machined surface F of the material M; an association unit 215 that associates the position data with the machined surface image; a waveform image generation unit 216 that generates a waveform image indicating a change in the position data or in a physical quantity on each of the plurality of control axes, based on the position data or based on the physical quantity, the physical quantity being acquired at timing when the position data is acquired, a selection unit 217 that selects a part of the machined surface image or a part of the waveform image; and a display unit 218 that displays, when a part of the machined surface image is selected, the waveform image corresponding to the part of the machined surface image, and displays, when a part of the waveform image is selected, a part of the machined surface image corresponding to the part of the waveform image on a display screen.

Therefore, the display device 20 enables the operator to easily grasp the correspondence relationship between the position of the workpiece on the machined surface F and the physical quantity on each control axis acquired when the machined surface F is being machined. Specifically, by the operator selecting a part of the machined surface image in which a flaw or the like is drawn, the display device 20 can display, on the display screen, a part of the waveform image corresponding to the part of the machined surface image in which the flaw is drawn. This enables the operator to estimate on which one of the plurality of control axes a defect has occurred.

When the operator estimates that an abnormality has occurred on the control axis in the waveform, the display device 20 can display, based on the operator's operation, a part of the machined surface image corresponding to a part of the waveform image. This enables the operator to quickly find a portion of the machined surface F on the machined surface F where a flaw or the like may occur.

The display device 20 may further include a reference surface data acquisition unit and a difference data acquisition unit.

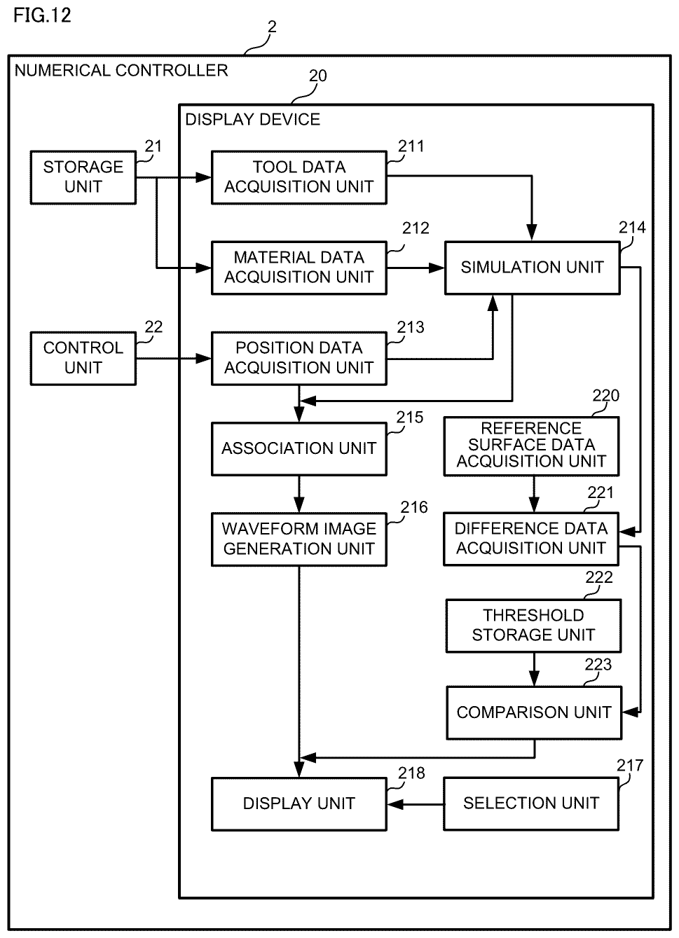

FIG. 11 is a block diagram illustrating an example of functions of a display device 20 that includes a reference surface data acquisition unit 220 and a difference data acquisition unit 221. The display device 20 illustrated in FIG. 11 differs from the display device 20 illustrated in FIG. 2 in including a reference surface data acquisition unit 220 and a difference data acquisition unit 221. Therefore, the reference surface data acquisition unit 220, the difference data acquisition unit 221, and functions related thereto will be described, and the description of the same functions as those described with reference to FIG. 2 will be omitted.

The reference surface data acquisition unit 220 and the difference data acquisition unit 221 are implemented, for example, by the hardware processor 201 performing arithmetic processing using the display program stored in the ROM 203 and various data stored in the non-volatile memory 205.

The reference surface data acquisition unit 220 acquires reference surface data indicating a reference surface serving as the reference of the machined surface F. The reference surface is a machined surface generated based on the material data, the tool data, and the movement path of the tool designated by the machining program. That is, the reference surface data is data of a surface indicating the ideal shape of the machined surface F.

The difference data acquisition unit 221 acquires difference data indicating a difference between the position of the reference surface indicated by the reference surface data and the position of the machined surface F indicated by the machined surface image generated by the simulation unit 214. That is, the difference data is data indicating the deviation of the shape of the machined surface F generated by the simulation from the shape of the machined surface having the ideal shape.

Based on the difference data, the display unit 218 displays the difference image indicating the difference on the machined surface F. The difference image is drawn, for example, by adding a predetermined color to the machined surface image.

The display device 20 may further include a threshold storage unit 222 that stores a threshold to be compared with the difference acquired by the difference data acquisition unit 221, and a comparison unit 223 that compares the difference with the threshold.

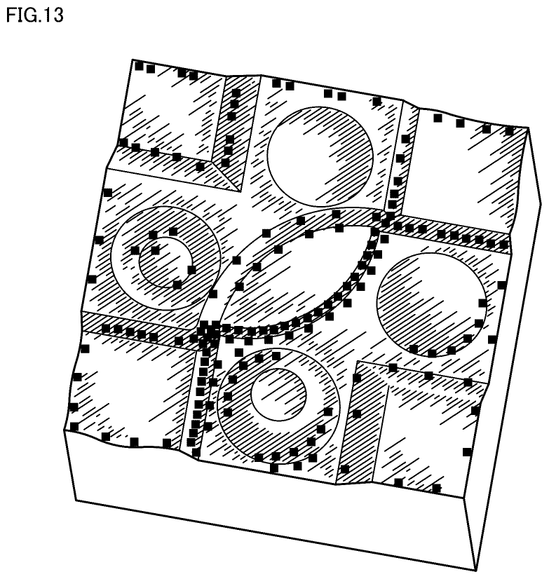

FIG. 12 is a diagram illustrating an example of functions of a display device 20 that includes the threshold storage unit 222 and the comparison unit 223. The display device 20 illustrated in FIG. 12 differs from the display device 20 illustrated in FIG. 11 in including a threshold storage unit 222 and a comparison unit 223. Therefore, here, the threshold storage unit 222, the comparison unit 223, and functions related thereto will be described, and the description of the same functions as those described with reference to FIG. 11 will be omitted.

The threshold storage unit 222 is implemented by storing data indicating the threshold in the RAM 204 or the non-volatile memory 205. The comparison unit 223 is implemented, for example, by the hardware processor 201 performing arithmetic processing using the display program stored in the ROM 203 and various data stored in the non-volatile memory 205.

The threshold storage unit 222 stores a threshold to be compared with the difference indicated by the difference data acquired by the difference data acquisition unit 221.

The comparison unit 223 compares the difference with the threshold. When the difference is equal to or larger than the threshold, the display unit 218 displays the difference image on the machined surface image based on the difference data. For example, the display unit 218 displays the difference image on the machined surface image by adding color to the machined surface image.

FIG. 13 is a diagram illustrating an example of the machined surface image on which a difference image is drawn. In FIG. 13, some portions of the machined surface image (portions indicated by black squares) are colored differently from the other portions. This enables the operator to recognize that some portions of the machined surface image colored differently from the other parts are portions with large deviations from the reference surface plane.

The threshold storage unit 222 may store a plurality of thresholds. For example, the threshold storage unit 222 may store a first threshold and a second threshold larger than the first threshold. In this case, the comparison unit 223 compares each value of the difference constituting the difference data with the first threshold and the second threshold.

The display unit 218 may classify each value of the difference into a group of values less than the first threshold, a group of values equal to or greater than the first threshold and less than the second threshold, and a group of values equal to or greater than the second threshold, and display difference images in different colors for each group. This enables the operator to estimate the deviation of the machined surface F generated by performing the machining from the ideal machined shape.

Note that the present disclosure is not limited to the above embodiment and can be appropriately changed without departing from the gist. In the present disclosure, it is possible to modify any component of the embodiment and to omit any component of the embodiment.

### REFERENCE SIGNS LIST

1 machining device
2 numerical controller
20 display device
21 storage unit
22 control unit
201 hardware processor
202 bus
203 ROM
204 RAM
205 non-volatile memory
206 interface
207 axis control circuit
208 spindle control circuit
209 PLC
210 I/O unit
211 tool data acquisition unit
212 material data acquisition unit
213 position data acquisition unit
214 simulation unit
215 association unit
216 waveform image generation unit
217 selection unit
218 display unit
219 physical quantity data acquisition unit
220 reference surface data acquisition unit
221 difference data acquisition unit
222 threshold storage unit
223 comparison unit
3 input/output device
4 servo amplifier
5 servo motor
6 spindle amplifier
7 spindle motor
8 auxiliary equipment

1. A display device comprising:
a tool data acquisition unit that acquires tool data indicating a shape of a tool;
a material data acquisition unit that acquires material data indicating a shape of a material;
a position data acquisition unit that acquires position data indicating a position on each of a plurality of control axes;
a simulation unit that executes a machining simulation, based on the tool data, the material data, and the position data to generate a machined surface image indicating a machined surface of the material;
an association unit that associates the position data with the machined surface image;
a waveform image generation unit that generates a waveform image indicating a change in the position data or in a physical quantity on each of the plurality of control axes, based on the position data or based on the physical quantity, the physical quantity being acquired at timing when the position data is acquired;
a selection unit that selects a part of the machined surface image or a part of the waveform image; and
a display unit that displays, when a part of the machined surface image is selected, the waveform image corresponding to the part of the machined surface image, and displays, when a part of the waveform image is selected, a part of the machined surface image corresponding to the part of the waveform image on a display screen.

2. The display device according to claim 1, wherein the physical quantity is at least one of speed, acceleration, jerk, or torque.

3. The display device according to claim 1 or 2, further comprising:
a reference surface data acquisition unit that acquires reference surface data indicating a reference surface to be a reference of the machined surface; and
a difference data acquisition unit that acquires difference data indicating a difference between a position of the reference surface and a position of the machined surface,
wherein based on the difference data, the display unit displays a difference image indicating the difference on the machined surface image.

4. The display device according to claim 3, further comprising
a threshold storage unit that stores a threshold to be compared with the difference, and
a comparison unit that compares the difference with the threshold,
wherein when the difference is equal to or greater than the threshold, the display unit displays the difference image on the machined surface image based on the difference data.

5. A computer-readable storage medium storing a command that causes a computer to execute
acquiring tool data that indicates a shape of a tool,
acquiring material data that indicates a shape of a material,
acquiring position data indicating a position on each of a plurality of control axes,
executing a machining simulation, based on the tool data, the material data, and the position data to generate a machined surface image indicating a machined surface of the material,
associating the position data with the machined surface image,
generating a waveform image indicating a change in the position data or in a physical quantity on each of the plurality of control axes, based on the position data or based on the physical quantity, the physical quantity being acquired at timing when the position data is acquired,
selecting a part of the machined surface image or a part of the waveform image, and
displaying, when a part of the machined surface image is selected, the waveform image corresponding to the part of the machined surface image, and displaying, when a part of the waveform image is selected, a part of the machined surface image corresponding to the part of the waveform image on a display screen.
